(19) United States
(12) Patent Application Publication
(10) Pub. No.: US 2026/0190330 A1
(43) Pub. Date: Jul. 2, 2026

(54) SEMICONDUCTOR DEVICE INCLUDING VERTICAL CHANNEL TRANSISTORS

(71) Applicant: Samsung Electronics Co., Ltd., Suwon-si (KR)

(72) Inventors: Seungmin LEE, Suwon-si (KR); Junghoon PARK, Suwon-si (KR); Junhyeon BAE, Suwon-si (KR); Kyongjun YOO, Suwon-si (KR)

(73) Assignee: Samsung Electronics Co., Ltd., Suwon-si (KR)

(21) Appl. No.: 19/429,005

(22) Filed: Dec. 22, 2025

(30) Foreign Application Priority Data
Dec. 31, 2024 (KR) 10-2024-0202663

(51) Int. Cl. H10B 12/00

(52) U.S. Cl. CPC H10B 12/485; H10B 12/05; H10B 12/33; H10B 12/50

(57) ABSTRACT

A semiconductor device may includes word lines extending in a first horizontal direction and spaced apart from each other in a second horizontal direction, wherein the word lines may include a conductive pattern extending in a vertical direction and may include first and second word lines adjacent to each other in the second horizontal direction; first and second gate insulating layers extending higher than the first and second word lines in the vertical direction on inner walls of the first and second word lines, respectively; first and second channel layers extending in the vertical direction on inner walls of the first and second gate insulating layers, respectively; a channel isolation insulating layer between the first and second channel layers; and a bit line contact plug below upper surfaces of the first and second channel layers, where the bit line contact plug may be on the channel isolation insulating layer.

### CROSS-REFERENCE TO RELATED APPLICATION

This application is based on and claims priority under 35 U.S.C. § 119 to Korean Patent Application No. 10-2024-0202663, filed on Dec. 31, 2024, in the Korean Intellectual Property Office, the disclosure of which is incorporated by reference herein in its entirety.

### BACKGROUND

Inventive concepts relate to a semiconductor device, and more particularly, to a semiconductor device including vertical channel transistors.

As design rules for semiconductor devices are decreasing, manufacturing technology for semiconductor devices is developing to improve the degree of integration and to enhance the operating speed and yield. Accordingly, vertical channel transistors have been proposed to improve the degree of integration, resistance, and/or current drive capability of transistors used in semiconductor devices.

### SUMMARY

Inventive concepts provide a semiconductor device including vertical channel transistors with improved electrical characteristics and/or device reliability.

According to an embodiment of inventive concepts, a semiconductor device may include: a plurality of word lines extending in a first horizontal direction and spaced apart from each other in a second horizontal direction, wherein the second horizontal direction may be perpendicular to the first horizontal direction, the plurality of word lines may include a conductive pattern, the conductive pattern may extend in a vertical direction, the vertical direction may be perpendicular to a plane in which the first horizontal direction extends and the second horizontal direction extends, the plurality of word lines may include a first word line and a second word line, and the first word line and the second word line may be adjacent to each other in the second horizontal direction; a first gate insulating layer on an inner wall of the first word line and a second gate insulating layer on an inner wall of the second word line, the first gate insulating layer extending higher than the first word line in the vertical direction and the second gate insulating layer extending higher than the second word line in the vertical direction; a first channel layer and a second channel layer extending in the vertical direction on an inner wall of the first gate insulating layer and an inner wall of the second gate insulating layer, respectively; a channel isolation insulating layer between the first channel layer and the second channel layer; a bit line contact plug below an upper surface of the first channel layer and an upper surface of the second channel layer, wherein the bit line contact plug may be on the channel isolation insulating layer, and the bit line contact plug may be in contact with both the first channel layer and the second channel layer; and a bit line electrically connected to the bit line contact plug, the bit line extending in the second horizontal direction.

According to an embodiment of inventive concepts, a semiconductor device may include: a plurality of word lines extending in a first horizontal direction and spaced apart from each other in a second horizontal direction, wherein the second horizontal direction may be perpendicular to the first horizontal direction, the plurality of word lines may include a conductive pattern, the conductive pattern may extend in a vertical direction, the vertical direction may be perpendicular to a plane in which the first horizontal direction extends and the second horizontal direction extends, the plurality of word lines may include a first word line and a second word line, and the first word line and the second word line may be adjacent to each other in the second horizontal direction; a first gate insulating layer on an inner wall of the first word line and a second gate insulating layer on an inner wall of the second word line, the first gate insulating layer extending higher than the first word line in the vertical direction and the second gate insulating layer extending higher than the second word line in the vertical direction; a first channel layer and a second channel layer extending higher in the vertical direction than the first word line and the second word line, the first channel layer being on an inner wall of the first gate insulating layer and the second channel layer being on an inner wall of the second gate insulating layer; a channel isolation insulating layer between the first channel layer and the second channel layer, the channel isolation insulating layer being lower than the first channel layer and the second channel layer in the vertical direction; a bit line contact plug on the channel isolation insulating layer and in contact with both the first channel layer and the second channel layer, wherein the bit line contact plug may be in an opening recessed below an upper surface of the first channel layer and an upper surface of the second channel layer and the opening may be defined by a space between the first channel layer and the second channel layer; a plurality of bit lines electrically connected to the bit line contact plug and extending in the second horizontal direction, the plurality of bit lines including a first bit line and a second bit line adjacent to each other in the first horizontal direction; and an interlayer insulating layer between the plurality of word lines, the interlayer insulating layer being outside of the first word line and the second word line, wherein the interlayer insulating layer may be between the first bit line and the second bit line in the first horizontal direction.

According to an embodiment of inventive concepts, a semiconductor device may include a peripheral circuit structure; and a cell array structure on the peripheral circuit structure. The cell array structure may include a plurality of word lines extending in a first horizontal direction and spaced apart from each other in a second horizontal direction, the second horizontal direction being perpendicular to the first horizontal direction, the plurality of word lines including a conductive pattern, the conductive pattern extending in a vertical direction, the vertical direction being perpendicular to a plane in which the first horizontal direction extends and the second horizontal direction extends, the plurality of word lines including a first word line and a second word line, and the first word line and the second word line being adjacent to each other in the second horizontal direction; a first gate insulating layer on an inner wall of the first word line and a second gate insulating layer on an inner wall of the second word line, the first gate insulating layer extending higher than the first word line in the vertical direction and the second gate insulating layer extending higher than the second word line in the vertical direction; a first channel layer and a second channel layer extending in the vertical direction on an inner wall of the first gate insulating layer and an inner wall of the second gate insulating layer, respectively; a channel isolation insulating layer between the first channel layer and the second channel layer; a bit line contact plug below an upper surface of the first channel layer and an upper surface of the second channel layer, wherein the bit line contact plug may be on the channel isolation insulating layer, and the bit line contact plug may be in contact with both the first channel layer and the second channel layer; a bit line electrically connected to the bit line contact plug, the bit line extending in the second horizontal direction; and data storage elements electrically connected respectively to the first channel layer and the second channel layer via landing pads in contact with the first channel layer and the second channel layer.

According to an embodiment of inventive concepts, a method of manufacturing a semiconductor device may include forming a plurality of data storage elements spaced apart from each other in a second horizontal direction on a substrate, the second horizontal direction crossing a first horizontal direction; forming a plurality of landing pads spaced apart from each other in the second horizontal direction on the plurality of data storage elements, respectively; forming a plurality of memory cells on alternate landing pads among the plurality of landing pads; and forming a bit line on the plurality of memory cells. The plurality of memory cells may each comprise a vertical channel transistor. The vertical channel transistor may include a first channel layer, a second channel layer, a first gate insulating layer, a second gate insulating layer, a first word line, a second word line, and two of the plurality of data storage elements. The first word line and the second word line may be among a plurality of word lines extending in the first horizontal direction and spaced apart from each other in the second horizontal direction, horizontal direction. The first word line and the second word line may be adjacent to each other in the second horizontal direction. The first gate insulating layer may be on an inner wall of the first word line and the second gate insulating layer is on an inner wall of the second word line. The first gate insulating layer may extend higher than the first word line in the vertical direction and the second gate insulating layer may extend higher than the second word line in the vertical direction. The forming the plurality of memory cells may include forming a channel isolation insulating layer between the first channel layer and the second channel layer, and a bit line contact plug on the channel isolation insulating layer. The bit line contact plug may be in contact with both the first channel layer and the second channel layer. The forming the bit line may include forming the bit line on the bit line contact plug so the bit line may be electrically connected to the bit line contact plug. The bit line may extend in the second horizontal direction.

In some embodiments, the method may further include forming a capping insulating layer over the plurality of word lines before the forming the bit line.

In some embodiments, the method may further include forming an air gap in the bit line contact plug before the forming the bit line.

In some embodiments, the forming the plurality of memory cells may include forming the first channel layer and the second channel layer from a semiconductor pattern comprising an oxide semiconductor.

In some embodiments, the bit line contact plug may be formed of a first bit line contact plug and a second bit line contact plug. The first bit line contact plug may be between the first gate insulating layer and the second gate insulating layer. The second bit line contact plug may be between the first bit line contact plug and the second bit line contact plug may be in contact with the first channel layer and the second channel layer.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to an embodiment;

FIG. 2 is a perspective view schematically showing a semiconductor device according to an embodiment;

FIG. 3 is a plan view of a semiconductor device according to an embodiment;

FIG. 4 is a perspective view illustrating a semiconductor device according to an embodiment;

FIG. 5 is a cross-sectional view of the semiconductor device in a bit line direction of FIG. 4;

FIG. 6 is a partially enlarged cross-sectional view of the semiconductor device of FIG. 5;

FIG. 7 is a cross-sectional view illustrating a region between bit line contact plugs of FIG. 4;

FIG. 8 is a three-dimensional perspective view illustrating a channel isolation insulating layer and a bit line contact plug of FIG. 4;

FIG. 9 is a three-dimensional perspective view illustrating a channel isolation insulating layer and a bit line sacrificial layer of FIG. 4;

FIGS. 10 to 18 are cross-sectional views illustrating a method of manufacturing a semiconductor device, according to an embodiment;

FIGS. 19 to 21 are cross-sectional views illustrating a method of manufacturing a semiconductor device, according to an embodiment;

FIG. 22 is a plan view of a memory module including a semiconductor device according to inventive concepts;

FIG. 23 is a schematic view of a memory card including a semiconductor device according to inventive concepts; and

FIG. 24 is a schematic view of a system including a semiconductor device according to inventive concepts.

### DETAILED DESCRIPTION OF THE EMBODIMENTS

Hereinafter, an embodiment is described in detail with reference to the accompanying drawings. Embodiments of inventive concepts may be made by using only one of embodiments described below or by using a combination of one or more embodiments. Accordingly, inventive concepts should not be construed as being limited to one embodiment.

As used herein, the singular forms include the plural forms as well, unless the context clearly indicates otherwise. In this specification, the drawings may be exaggerated to more clearly describe aspects of inventive concepts.

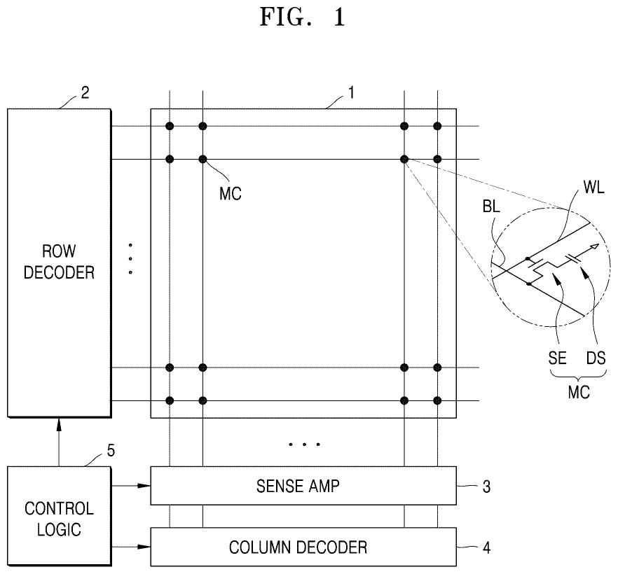

FIG. 1 is a block diagram of a semiconductor device according to an embodiment.

Specifically, in some embodiments, the semiconductor device shown in FIG. 1 may include a memory device. In some embodiments, the semiconductor device shown in FIG. 1 may include a dynamic random-access memory (DRAM) device. The semiconductor device may include a memory cell array 1, a row decoder 2, a sense amplifier 3, a column decoder 4, and control logic 5. The memory cell array 1 may include a plurality of memory cells MC arranged in two dimensions or three dimensions.

Each of the memory cells MC may be connected between a word line WL and a bit line BL that intersect each other. Each of the memory cells MC may include a selection element SE and a data storage element DS. The selection element SE may be electrically connected in series to the data storage element DS.

The selection element SE may be connected between the data storage element DS and the word line WL. The data storage element DS may be connected to the bit line BL via the selection element SE. The selection element SE may include a transistor.

The selection element SE may include a vertical channel transistor (VCT). The selection element SE may include a field effect transistor (FET). The data storage element DS may be formed as a capacitor.

For example, a gate electrode of the transistor may be connected to the word line WL, and drain/source terminals of the transistor may be connected to the bit line BL and the data storage element DS, respectively.

The row decoder 2 may decode an address input from the outside and select one of the word lines WL of the memory cell array 1. The address decoded by the row decoder 2 may be provided to a row driver (not shown). In response to a control signal from the control logic 5, the row driver may provide a certain voltage to each of a selected word line WL and unselected word lines WL.

The sense amplifier 3 may sense, amplify, and output the difference in voltage between a selected bit line BL and a reference bit line according to the address decoded from the column decoder 4. The column decoder 4 may provide a data transmission path between the sense amplifier 3 and an external device (e.g., a memory controller). The column decoder 4 may decode an address input from the outside and select any one of bit lines BL. The control logic 5 may generate control signals for controlling operations of writing or reading data into or from the memory cell array 1.

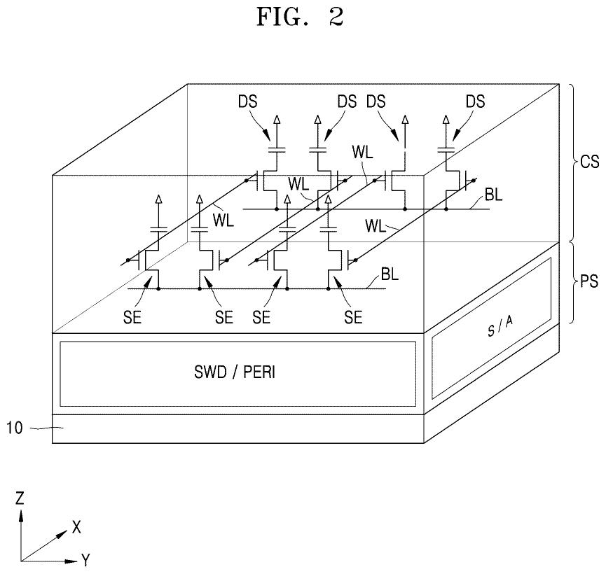

FIG. 2 is a perspective view schematically showing a semiconductor device according to an embodiment.

Specifically, the semiconductor device may include a peripheral circuit structure PS located on a substrate 10 and a cell array structure CS located on the peripheral circuit structure PS. The substrate 10 may include a peripheral circuit substrate. The peripheral circuit structure PS may include a core circuit and a peripheral circuit formed on the substrate 10. The peripheral circuit structure PS may include the core circuit and the peripheral circuit for operating the cell array structure CS.

The peripheral circuit structure PS may include a peripheral circuit PERI, which includes the row and column decoders 2 and 4 (FIG. 1), and the sense amplifier 3 (FIG. 1), the control logic 5 (FIG. 1) described above, and a source word line driver circuit SWD. The peripheral circuit structure PS may be provided between the substrate 10 and the cell array structure CS in a vertical direction (a Z direction) perpendicular to the upper surface of the substrate 10.

The cell array structure CS may include bit lines BL, word lines WL, and the memory cells MC (FIG. 1) located therebetween. The memory cells MC (FIG. 1) may be arranged in two dimensions or three dimensions on a plane extending in first and second horizontal directions (X and Y directions) that intersect each other and are parallel to the upper surface of the substrate 10.

As used herein, a word line direction may represent the first horizontal direction (the X direction). A bit line direction may represent the second horizontal direction (the Y direction). A direction perpendicular to the substrate 10 may represent the vertical direction (the Z direction). The direction perpendicular to the plane extending in the first and second horizontal directions (the X and Y directions) may represent the vertical direction (the Z direction).

Each of the memory cells MC (FIG. 1) may include the selection element SE and the data storage element DS as described above. Each of the memory cells MC (FIG. 1) may include a VCT as the selection element SE. The VCT may represent a structure in which a channel extends lengthwise in a direction (the Z direction) perpendicular to the upper surface of the substrate 10. The VCT constituting the memory cells MC (FIG. 1) may include first and second channel layers, first and second gate insulating layers, and first and second word lines, which are described below. Each of the memory cells MC (FIG. 1) may include a capacitor as data storage elements DS.

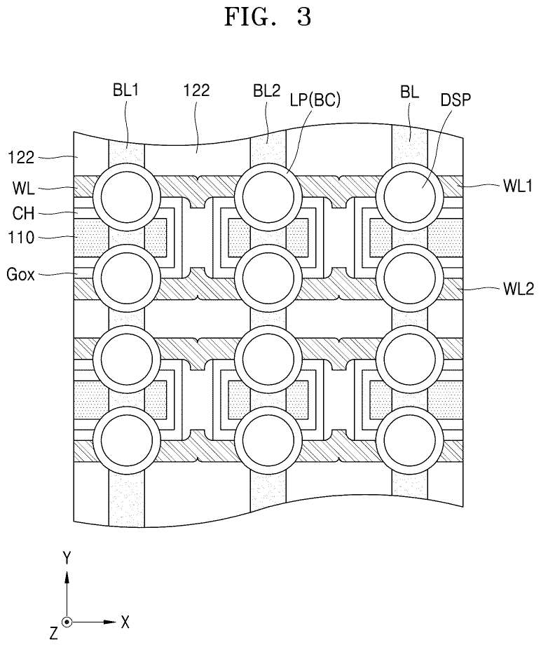

FIG. 3 is a plan view of a semiconductor device according to an embodiment.

Specifically, the semiconductor device is provided to describe the cell array structure CS (FIG. 2). The cell array structure CS (FIG. 2) may include memory cells including VCTs.

The semiconductor device may include a plurality of word lines WL, a plurality of bit lines BL, channel layers CH, gate insulating layers Gox, a channel isolation insulating layer 110, a third interlayer insulating layer 122, a plurality of landing pads LP, and a plurality of data storage patterns DSP. The landing pads LP may also be referred to as buried contacts BC.

The word lines WL extend in the first horizontal direction (the X direction) and are spaced apart from each other in the second horizontal direction (the Y direction) that is perpendicular to the first horizontal direction (the X direction). The word lines WL include a first word line WL1 and a second word line WL2, which are adjacent to each other in the second horizontal direction (the Y direction).

The bit lines BL extend in the second horizontal direction (the Y direction) and are spaced apart from each other in the first horizontal direction (the X direction). The bit lines BL include a first bit line BL1 and a second bit line BL2, which are adjacent to each other in the second horizontal direction (the Y direction).

The channel layers CH may be arranged below the bit lines BL. The channel layers CH may be spaced apart from each other in the first and second horizontal directions (the X and Y directions). The gate insulating layers Gox may be arranged between the channel layers CH and the word lines WL. The word lines WL may be spaced apart from the channel layers CH by the gate insulating layers Gox.

The channel isolation insulating layer 110 may be located between the first word line WL1 and the second word line WL2 in the second horizontal direction (the Y direction). The channel isolation insulating layer 110 may be located between two channel layers CH in the second horizontal direction (the Y direction).

The third interlayer insulating layer 122 may be located outside of the first word line WL1 and the second word line WL2 in the second horizontal direction (the Y direction). The third interlayer insulating layer 122 may be located between the gate insulating layers Gox in the first horizontal direction (the X direction). The channel isolation insulating layer 110 and the third interlayer insulating layer 122 may be arranged between the bit lines BL and between the word lines WL in the first horizontal direction (the X direction) and the second horizontal direction (the Y direction).

The landing pads LP may be arranged below the channel layers CH. The landing pads LP may be spaced apart from each other in the first and second horizontal directions (the X and Y directions) in a plan view. The landing pads LP may be arranged in various forms, such as matrix, zigzag, and honeycomb patterns. In a plan view, each of the landing pads LP may have various shapes, such as circular, elliptical, rectangular, square, rhombic, and hexagonal shapes.

The data storage patterns DSP may be provided below the landing pads LP. The data storage patterns DSP may represent part of the data storage element DS in FIG. 2. The data storage patterns DSP may be electrically connected to the channel layers CH via the landing pads LP. The data storage patterns DSP may include a capacitor.

The capacitor may include a lower electrode, an upper electrode, and a capacitor dielectric layer located therebetween. In this case, the lower electrode may be in contact with a landing pad LP. In a plan view, the lower electrode may have various shapes, such as circular, elliptical, rectangular, square, rhombic, and hexagonal shapes. The memory cells described above may include the VCT, which includes the channel layers CH, first and second gate insulating layers Gox, and the word lines WL, and a data storage pattern DSP.

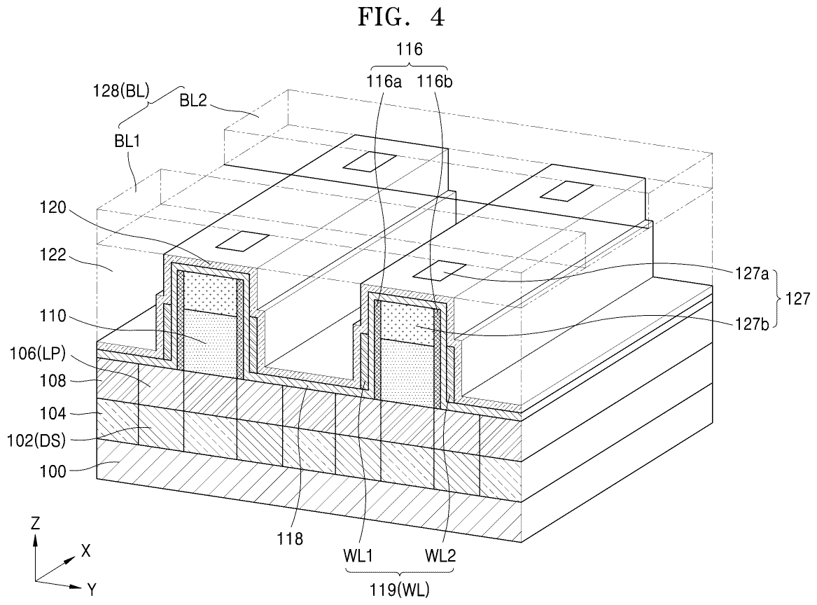

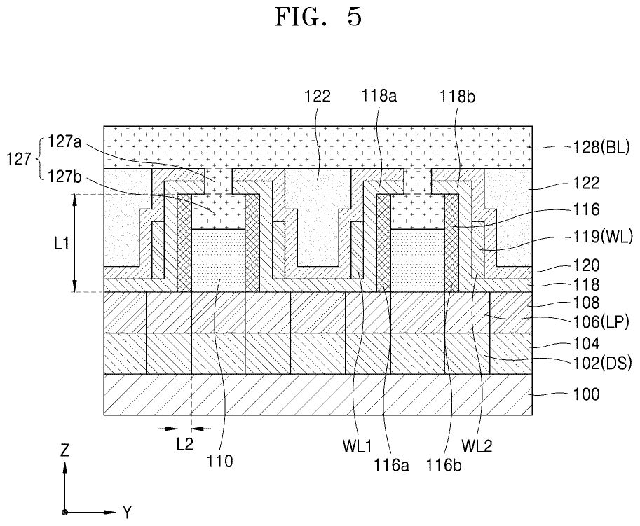

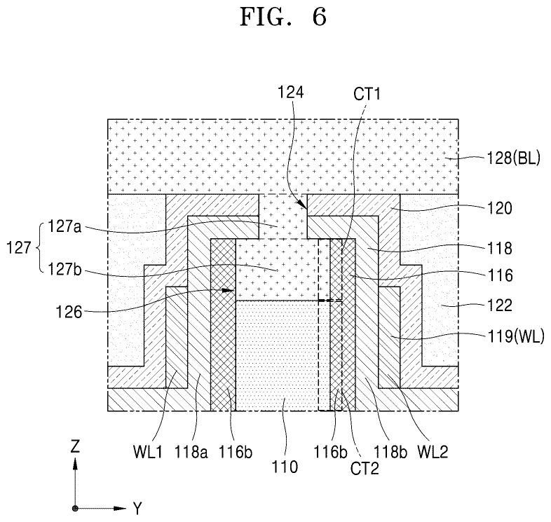

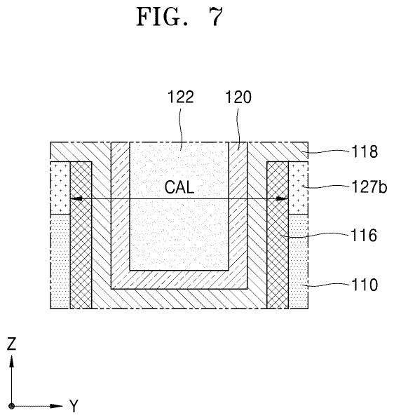

FIG. 4 is a perspective view illustrating a semiconductor device according to an embodiment, FIG. 5 is a cross-sectional view of the semiconductor device in a bit line direction of FIG. 4; FIG. 6 is a partially enlarged cross-sectional view of the semiconductor device of FIG. 5; and FIG. 7 is a cross-sectional view illustrating a region between bit line contact plugs of FIG. 4.

Specifically, the semiconductor device of FIG. 4 is provided to illustrate the cell array structure CS (FIG. 2). FIG. 4 may show a three-dimensional view of the semiconductor device according to an embodiment of inventive concepts. FIG. 4 illustrates that the semiconductor device is formed on a substrate 100, but the substrate 100 may be removed for bonding with the peripheral circuit structure PS (FIG. 2). The substrate 100 may include a carrier substrate. The substrate 100 may include a semiconductor substrate. The substrate 100 may include a silicon substrate, a germanium substrate, or a silicon-germanium substrate.

The semiconductor device may include data storage elements 102 and a first interlayer insulating layer 104, which are arranged on the substrate 100. The data storage elements 102 may correspond to the data storage elements DS of FIG. 2 or the data storage patterns DSP of FIG. 3. The data storage elements 102 may be provided as a capacitor.

The semiconductor device may include landing pads 106 and a second interlayer insulating layer 108, which are arranged on the data storage elements 102 and the first interlayer insulating layer 104, respectively. The landing pads 106 may correspond to the landing pads LP of FIG. 3. The landing pads 106 may be provided to connect the data storage elements DS or the data storage patterns DSP to each other. The landing pads 106 may be referred to as buried contacts BC (FIG. 3).

The first and second interlayer insulating layers 104 and 108 may include at least one of silicon oxide, silicon nitride, and silicon oxynitride. The first and second interlayer insulating layers 104 and 108 may be formed as a single layer or multi-layers including the materials stated above. In the embodiment, the first interlayer insulating layer 104 may include silicon oxide and the second interlayer insulating layer 108 may include silicon nitride.

The landing pads 106 may be provided to connect the data storage elements 102 to first and second channel layers 116a and 116b below the first and second word lines WL1 and WL2, respectively. The landing pads 106 may include, but are not limited to, doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

The second interlayer insulating layer 108 may be formed between the landing pads 106 and on the first interlayer insulating layer 104. The first and second interlayer insulating layers 104 and 108 may include at least one of silicon oxide, silicon nitride, and silicon oxynitride. The first and second interlayer insulating layers 104 and 108 may be formed as a single layer or multi-layers including the materials stated above. In the embodiment, the first and second interlayer insulating layers 104 and 108 may include silicon oxide.

The semiconductor device may include a plurality of word lines 119, a plurality of channel layers 116, a plurality of gate insulating layers 118, a channel isolation insulating layer 110, a bit line contact plug 127, a plurality of bit lines 128, and a third interlayer insulating layer 122.

The word lines 119 may correspond to the word lines WL of FIG. 3. The word lines 119 may extend in the first horizontal direction (the X direction) above the substrate 100 and extend in the vertical direction (the Z direction) from the substrate 100.

The word lines 119 may be spaced apart from each other in the second horizontal direction (the Y direction) perpendicular to the first horizontal direction. The word lines 119 may include conductive patterns that extend in the vertical direction (the Z direction) perpendicular to a plane extending in the first and second horizontal directions (the X and Y directions). In some embodiments, the word lines 119 may each have a width of several nm to several tens of nm.

The word lines 119 may include, but are not limited to, at least one of doped polysilicon, metal (e.g., Al, Cu, Ti, Ta, Ru, W, Mo, Pt, Ni, and Co), conductive metal nitride (e.g., TiN, TaN, WN, NbN, TiAlN, TiSiN, TaSiN, and RuTiN), conductive metal silicide, and conductive metal oxide (e.g., PtO, RuO₂, IrO₂, SRO(SrRuO3), BSRO((Ba, Sr)RuO₃), CRO(CaRuO₃), and LSCo).

The word lines 119 may include a single layer or multi-layers including the materials stated above. In some embodiments, the word lines 119 may include a two-dimensional semiconductor material. For example, the two-dimensional semiconductor material may include graphene, carbon nanotubes, or a combination thereof.

The word lines 119 may include the first word line WL1 and the second word line WL2, which are adjacent to each other. The first word line WL1 may be adjacent to the second word line WL2 in the second horizontal direction (the Y direction). The first word line WL1 and the second word line WL2 may be arranged at locations facing each other in the second horizontal direction (the Y direction).

The gate insulating layers 118 may be arranged on the inner walls of the first and second word lines WL1 and WL2 and extend vertically higher than the word lines 119. The gate insulating layers 118 may correspond to the gate insulating layers Gox of FIG. 3. The gate insulating layers 118 may include first and second gate insulating layers 118a and 118b, which are formed on sidewalls of the first and second word lines WL1 and WL2, respectively.

The first and second gate insulating layers 118a and 118b may be formed on the outer walls of the first and second channel layers 116a and 116b, respectively. The first and second gate insulating layers 118a and 118b may extend from the outer walls of the first and second channel layers 116a and 116b onto the upper surfaces of the first and second channel layers 116a and 116b and onto the upper surface of a second bit line contact plug 127b. The gate insulating layers 118 may be formed between the channel layers 116 and the first and second word lines WL1 and WL2. In some embodiments, the thickness of each of the gate insulating layers 118 may be several nm.

The gate insulating layers 118 may include at least one of silicon oxide, silicon oxynitride, and a high-k dielectric material having a higher dielectric constant than the silicon oxide. The high-k dielectric material may include metal oxide or metal oxynitride. For example, the high-k dielectric materials that may be used as the gate insulating layers 118 may include, but are not limited to, at least one of HfO₂, HfSiO, HfSiON, HfTaO, HfTiO, HfZrO, ZrO₂, and Al₂O₃.

The channel layers 116 may be located on sidewalls of the gate insulating layers 118 and extend in the vertical direction (the Z direction). The channel layers 116 may correspond to the channel layers CH of FIG. 3. The channel layers 116 may extend in the vertical direction (the Z direction) outside of the outer walls of the first and second word lines WL1 and WL2.

The channel layers 116 may include source and drain regions above and below the word lines 119, respectively, in the vertical direction (the Z direction). In some embodiments, the thickness of each of the channel layers 116 may be several nm. The channel layers 116 may include the first and second channel layers 116a and 116b, which are formed on the inner walls of the first and second gate insulating layers 118a and 118b, respectively. The upper surfaces of the first and second channel layers 116a and 116b may be higher than the upper surfaces of the word lines 119 in the vertical direction (the Z direction).

As shown in FIG. 5, a length L2 of each of the first and second channel layers 116a and 116b in the second horizontal direction (the Y direction) may be less than a length L1 of each of the first and second channel layers 116a and 116b in the vertical direction (the Z direction). As shown in FIG. 6, the first and second channel layers 116a and 116b may each include a first contact section CT1 in contact with the second bit line contact plug 127b and a second contact section CT2 in contact with the channel isolation insulating layer 110.

The second bit line contact plug 127b of the first contact section CT1 may be formed inside a second contact hole 126, thereby easily adjusting a vertical contact length between the second bit line contact plug 127b of the first contact section CT1 and the first and second channel layers 116a and 116b.

The channel layers 116 may be referred to as semiconductor patterns. The channel layers 116 may include an oxide semiconductor. The oxide semiconductor may include, but is not limited to, at least one of InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, and InxGayO.

In some embodiments, the channel layers 116 may include indium gallium zinc oxide (IGZO). The channel layers 116 may include a single layer or multi-layers of oxide semiconductors. The channel layers 116 may include amorphous, crystalline, or polycrystalline oxide semiconductors.

In some embodiments, the channel layers 116 may have band gap energy greater than band gap energy of silicon. The channel layers 116 may have band gap energy of about 1.5 eV to about 5.6 eV. The channel layers 116 may exhibit optimal channel performance when having band gap energy of about 2.0 eV to about 4.0 eV. The channel layers 116 may include a two-dimensional semiconductor material. For example, the two-dimensional semiconductor material may include graphene, carbon nanotubes, or a combination thereof.

The channel isolation insulating layer 110 may be located between the first and second channel layers 116a and 116b. The channel isolation insulating layer 110 may isolate and insulate the first and second channel layers 116a and 116b from each other. The channel isolation insulating layer 110 may be at a lower height than the upper surfaces of the first and second channel layers 116a and 116b.

The channel isolation insulating layer 110 may include at least one of silicon oxide, silicon nitride, and silicon oxynitride. The channel isolation insulating layer 110 may be formed as a single layer or multi-layers including the materials stated above. In the embodiment, the channel isolation insulating layer 110 may include silicon oxide.

The bit line contact plug 127 may be disposed on the channel isolation insulating layer 110. The bit line contact plug 127 may be located below the upper surfaces of the first and second channel layers 116a and 116b and be thus in contact with both the first and second channel layers 116a and 116b. The bit line contact plug 127 may include a first bit line contact plug 127a and the second bit line contact plug 127b.

In some embodiments, the semiconductor device may further include a capping insulating layer 120, which is formed on the upper surfaces and side surfaces of the first and second word lines WL1 and WL2, on the upper surfaces and side surfaces of the first and second gate insulating layers 118a and 118b, and above the second bit line contact plug 127b. In some embodiments, the thickness of the capping insulating layer 120 may be several nm.

The capping insulating layer 120 may include at least one of silicon oxide, silicon nitride, and silicon oxynitride. The capping insulating layer 120 may be formed as a single layer or multi-layers including the materials stated above. In the embodiment, the capping insulating layer 120 may include silicon nitride.

The first bit line contact plug 127a may be formed inside a first contact hole 124 that passes through the capping insulating layer 120 and the first and second gate insulating layers 118a and 118b located on the second bit line contact plug 127b. The second bit line contact plug 127b may be formed inside a second contact hole 126 that is located on the channel isolation insulating layer 110 and below the upper surfaces of the first and second channel layers 116a and 116b. Accordingly, the second bit line contact plug 127b may be in contact with both the first and second channel layers 116a and 116b.

The third interlayer insulating layer 122 may be located between the outer walls of the word lines 119. The third interlayer insulating layer 122 may be located between the bit lines 128. The third interlayer insulating layer 122 may be formed between capping insulating layers 120 between the bit lines 128. The third interlayer insulating layer 122 is also illustrated in FIG. 3.

The third interlayer insulating layer 122 may include at least one of silicon oxide, silicon nitride, and silicon oxynitride. The third interlayer insulating layer 122 may be formed as a single layer or multi-layers including the materials stated above. In the embodiment, the third interlayer insulating layer 122 may include silicon oxide.

The bit lines 128 may be electrically connected to the bit line contact plug 127. The bit lines 128 may be located on the first bit line contact plug 127a and electrically connected to the first bit line contact plug 127a. The bit lines 128 may correspond to the bit line BL of FIG. 3. The bit lines BL extend in the second horizontal direction (the Y direction) and are spaced apart from each other in the first horizontal direction (the X direction). The bit lines BL include the first bit line BL1 and the second bit line BL2, which are adjacent to each other in the second horizontal direction (the Y direction).

The bit lines 128 may be formed as a conductive pattern. The bit lines 128 may include the same material as the bit line contact plug 127. The bit lines 128 may form a single body with the bit line contact plug 127.

The bit lines 128 may include, but are not limited to, at least one of doped polysilicon, metal (e.g., Al, Cu, Ti, Ta, Ru, W, Mo, Pt, Ni, and Co), conductive metal nitride (e.g., TiN, TaN, WN, NbN, TiAlN, TiSiN, TaSiN, and RuTiN), conductive metal silicide, and conductive metal oxide (e.g., PtO, RuO₂, IrO₂, SRO(SrRuO₃), BSRO((Ba, Sr)RuO₃), CRO(CaRuO₃), and LSCo).

The bit lines 128 may include a single layer or multi-layers including the materials stated above. In some embodiments, the bit lines 128 may include a two-dimensional semiconductor material, and the two-dimensional semiconductor material may include graphene, carbon nanotubes, or a combination thereof.

As described above, the first and second channel layers 116a and 116b may be respectively located on sidewalls of the second bit line contact plug 127b. Accordingly, as shown in FIG. 7, a distance CAL between the inner walls of second bit line contact plugs 127b may increase in the second horizontal direction (the Y direction). In the semiconductor device, the distance CAL between the first bit line BL1 and the second bit line BL2 may be increased in the second horizontal direction (the Y direction), thereby reducing a bit line capacitance. Accordingly, in the semiconductor device according to an embodiment of inventive concepts, the electrical characteristics thereof may be improved by reducing signal delay.

Also, the semiconductor device according to an embodiment of inventive concepts may include the bit line contact plug 127, located below the upper surfaces of the first and second channel layers 116a and 116b, and the bit lines 128, electrically connected to the bit line contact plug 127. Accordingly, one bit line 128 of the semiconductor device according to an embodiment of inventive concepts may share two channel layers, e.g., the first and second channel layers 116a and 116b, thus improving the degree of integration.

The semiconductor device according to inventive concepts may be provided with the bit line contact plug 127 that is in contact with the sidewalls of the channel layers 116, thereby increasing a contact area between the bit line contact plug 127 and the first and second channel layers 116a and 116b. Accordingly, the semiconductor device according to inventive concepts may reduce bit line contact resistance, thereby increasing electrical characteristics, such as current drive capability.

In addition, in the semiconductor device according to an embodiment of inventive concepts, the bit line contact plug 127, e.g., the second bit line contact plug 127b, may be located inside the second contact hole 126, thereby easily adjusting the contact length between the second bit line contact plug 127b and the first and second channel layers 116a and 116b and improving the device reliability.

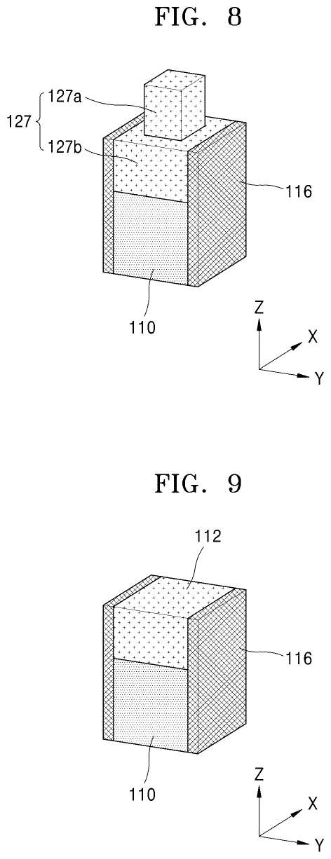

FIG. 8 is a three-dimensional perspective view illustrating a channel isolation insulating layer and a bit line contact plug of FIG. 4, and FIG. 9 is a three-dimensional perspective view illustrating the channel isolation insulating layer and a bit line sacrificial layer of FIG. 4.

Specifically, in FIGS. 8 and 9, the same reference numerals as in FIGS. 4 to 7 indicate the same members. As shown in FIG. 8, the channel isolation insulating layer 110 may be located between the channel layers 116. The bit line contact plug 127 may be located on the channel isolation insulating layer 110.

The bit line contact plug 127 may include the first bit line contact plug 127a and the second bit line contact plug 127b. The first bit line contact plug 127a may have a less capacity (volume) than the second bit line contact plug 127b.

As shown in FIG. 9, the channel isolation insulating layer 110 may be located between the channel layers 116. A bit line sacrificial layer 112 may be located on the channel isolation insulating layer 110. The bit line sacrificial layer 112 may include an insulating layer. In a region of the semiconductor device, in which the bit line contact plug 127 is not formed, the bit line sacrificial layer 112 may be formed to limit and/or prevent electrical connections between the channel layers 116 and the bit lines 128.

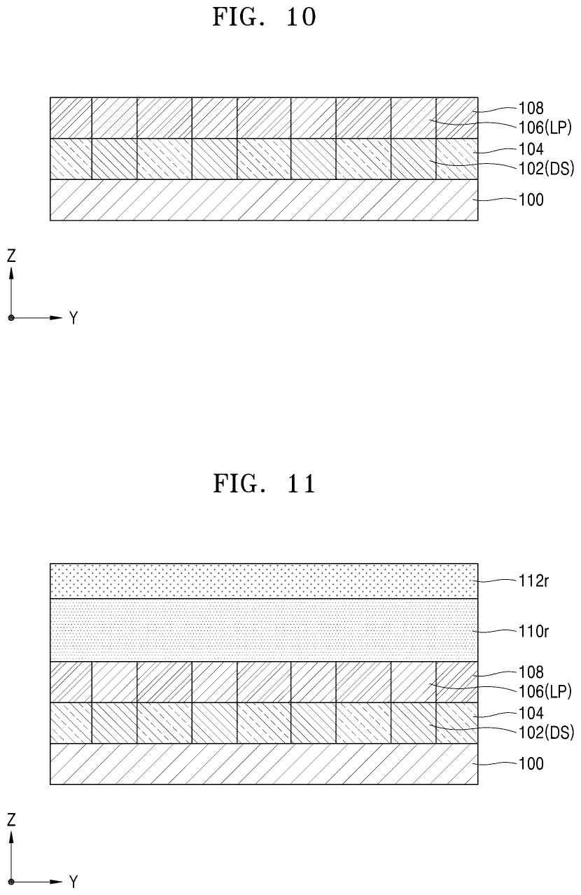

FIGS. 10 to 18 are cross-sectional views illustrating a method of manufacturing a semiconductor device, according to an embodiment.

Specifically, in FIGS. 10 to 18, the same reference numerals as in FIGS. 4 to 9 indicate the same members. The descriptions given above with reference to FIGS. 4 to 9 are briefly given or omitted when describing FIGS. 10 to 18.

Referring to FIG. 10, the data storage elements 102 and the first interlayer insulating layer 104 are formed on the substrate 100. The substrate 100 may include a semiconductor substrate. The substrate 100 may include a silicon substrate, a germanium substrate, or a silicon-germanium substrate.

The first interlayer insulating layer 104 may insulate the data storage elements 102 from each other. The data storage elements 102 may correspond to the data storage elements DS of FIG. 2 or the data storage patterns DSP of FIG. 3. The data storage elements 102 may be provided as a capacitor.

The landing pads 106 and the second interlayer insulating layer 108 are formed on the data storage elements 102 and the first interlayer insulating layer 104, respectively. The second interlayer insulating layer 108 may insulate the landing pads 106 from each other. The landing pads 106 may correspond to the landing pads LP of FIG. 3. The landing pads 106 may electrically connect the data storage elements DS or the data storage patterns DSP to each other. The landing pads 106 may be referred to as the buried contacts BC (FIG. 3).

Referring to FIG. 11, a channel isolation insulating material layer 110r is formed on the landing pads 106 and the second interlayer insulating layer 108. The channel isolation insulating material layer 110r may include a mold insulating material layer. The channel isolation insulating material layer 110r may include at least one of silicon oxide, silicon nitride, and silicon oxynitride.

The channel isolation insulating material layer 110r may be formed as a single layer or multi-layers including the materials stated above. In the embodiment, the channel isolation insulating material layer 110r may include silicon oxide.

A bit line sacrificial material layer 112r is formed on the channel isolation insulating material layer 110r. The bit line sacrificial material layer 112r may include at least one of silicon oxide, silicon nitride, and silicon oxynitride. The bit line sacrificial material layer 112r may be formed as a single layer or multi-layers including the materials stated above. In the embodiment, the bit line sacrificial material layer 112r may include silicon nitride.

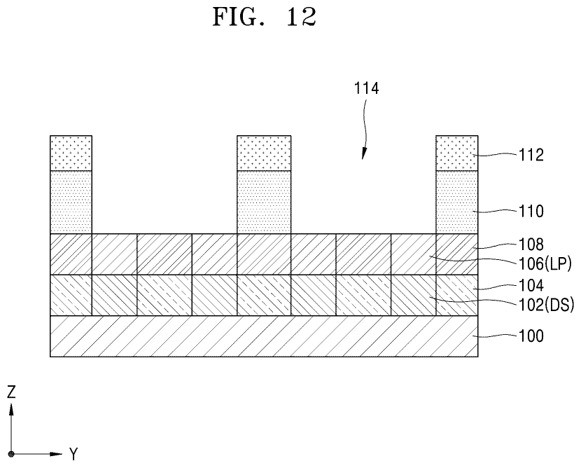

Referring to FIG. 12, the bit line sacrificial material layer 112r and the channel isolation insulating material layer 110r are patterned, thereby forming the bit line sacrificial layer 112 and the channel isolation insulating layer 110. The bit line sacrificial material layer 112r and the channel isolation insulating material layer 110r may be patterned by using a photo-etching process.

As the bit line sacrificial material layer 112r and the channel isolation insulating material layer 110r are patterned, a mold trench 114 for exposing the landing pads 106 and the second interlayer insulating layer 108 may be formed inside the bit line sacrificial layer 112 and the channel isolation insulating layer 110. In other words, the bit line sacrificial layer 112 and the channel isolation insulating layer 110 may have the mold trench 114 through which the landing pads 106 and the second interlayer insulating layer 108 are exposed.

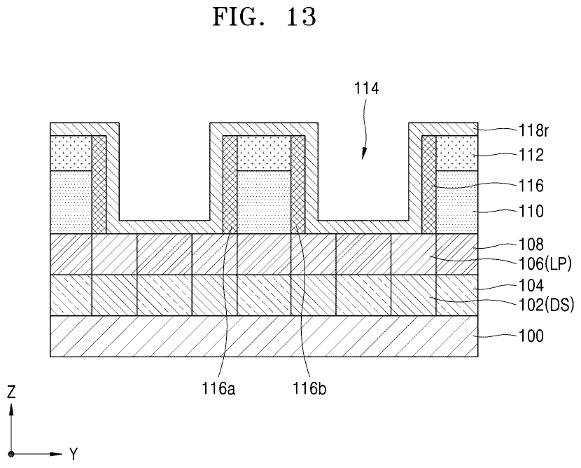

Referring to FIG. 13, the channel layers 116 are formed on the inner wall of the mold trench 114. The channel layers 116 may be formed on sidewalls of the bit line sacrificial layer 112 and the channel isolation insulating layer 110. The channel layers 116 may be formed on both sidewalls of the bit line sacrificial layer 112 and the channel isolation insulating layer 110, which face each other. The channel layers 116 may include the first and second channel layers 116a and 116b facing each other.

The channel layers 116 may be formed by forming a channel material layer on the resulting structure of FIG. 12, in which the mold trench 114 has been formed, and then patterning the channel material layer by a photo-etching process. The channel layers 116 may include a semiconductor pattern including an oxide semiconductor.

A gate insulating material layer 118r is formed on the bit line sacrificial layer 112, the channel layers 116, and the mold trench 114. The gate insulating material layer 118r may be formed at the bottom of the mold trench 114, on the sidewalls and upper surfaces of the channel layers 116, on the upper surface of the bit line sacrificial layer 112, and on the upper surfaces of the landing pads 106 and the second interlayer insulating layer 108.

The gate insulating material layer 118r may include a material including at least one of silicon oxide, silicon oxynitride, and a high-k dielectric material having a higher dielectric constant than the silicon oxide.

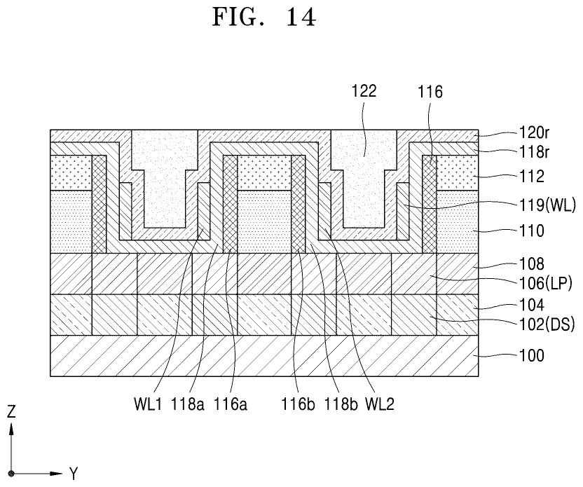

Referring to FIG. 14, the word lines 119 are formed on sidewalls of the gate insulating material layer 118r inside the mold trench 114 (FIG. 13). The word lines 119 may be spaced apart from each other in the second horizontal direction (the Y direction). The word lines 119 may have lower heights than the upper surfaces of the channel layers 116. The word lines 119 may extend in the vertical direction (the Z direction) on the gate insulating material layer 118r. The word lines 119 may be formed above the outer walls of the channel layers 116.

The word lines 119 may include the first word line WL1 and the second word line WL2, which are adjacent to each other. The first word line WL1 may be adjacent to the second word line WL2 in the second horizontal direction (the Y direction).

The first and second word lines WL1 and WL2 may be formed above the outer walls of the first and second channel layers 116a and 116b, respectively, with the gate insulating material layer 118r therebetween. The gate insulating material layer 118r may include a first gate insulating layer 118a formed on one sidewall of the first channel layer 116a and a second gate insulating layer 118b formed on one sidewall of the second channel layer 116b.

A capping insulating material layer 120r is formed on the gate insulating material layer 118r and the word lines 119 in the mold trench 114 (FIG. 13). The capping insulating material layer 120r may be formed on the upper surface of the gate insulating material layer 118r and on the upper surfaces and sidewalls of the word lines 119. The capping insulating material layer 120r may include at least one of silicon oxide, silicon nitride, and silicon oxynitride. The capping insulating material layer 120r may be formed as a single layer or multi-layers including the materials stated above. In the embodiment, the capping insulating material layer 120r may include silicon nitride.

Subsequently, the third interlayer insulating layer 122 is formed on the capping insulating material layer 120r to fill the inside of the mold trench 114 (FIG. 13). A third interlayer insulating material layer may be formed on the capping insulating material layer 120r to fill the inside of the mold trench 114 (FIG. 13) and then planarized, thereby forming the third interlayer insulating layer 122.

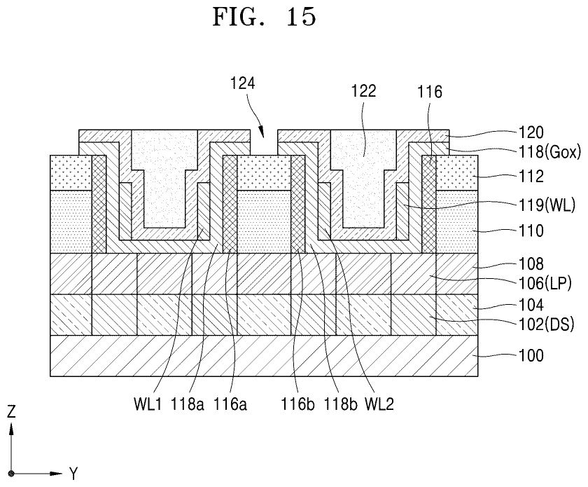

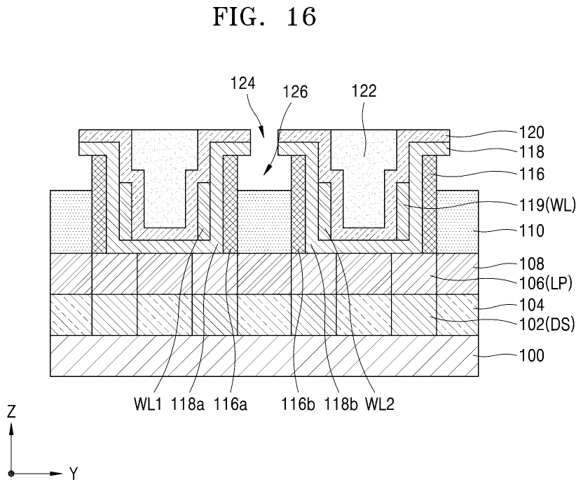

Referring to FIG. 15, the capping insulating material layer 120r and the gate insulating material layer 118r on the bit line sacrificial layer 112 are patterned, thereby forming the first contact hole 124. The first contact hole 124 may expose the upper surface of the bit line sacrificial layer 112. The first contact hole 124 may be formed by patterning the capping insulating material layer 120r and the gate insulating material layer 118r by a photo-etching process.

As the capping insulating material layer 120r and the gate insulating material layer 118r are patterned, the capping insulating material layer 120r and the gate insulating material layer 118r may become the capping insulating layer 120 and the gate insulating layers 118, respectively. The gate insulating layers 118 may correspond to the gate insulating layers Gox of FIG. 3. The gate insulating layers 118 may include the first and second gate insulating layers 118a and 118b, which are formed on sidewalls of the first and second word lines WL1 and WL2, respectively.

Referring to FIG. 16, the bit line sacrificial layer 112, exposed through the first contact hole 124, is etched to form the second contact hole 126. The first contact hole 124 and the second contact hole 126 may be connected to each other.

The second contact hole 126 may have a greater width (or diameter) than the first contact hole 124. As the second contact hole 126 is formed, the upper surface of the channel isolation insulating layer 110 and the inner surfaces of the first and second channel layers 116a and 116b may be exposed. As described with reference to FIG. 9, in the region in which the bit line contact plug 127 is not formed, the bit line sacrificial layer 112 may not be etched during a subsequent process.

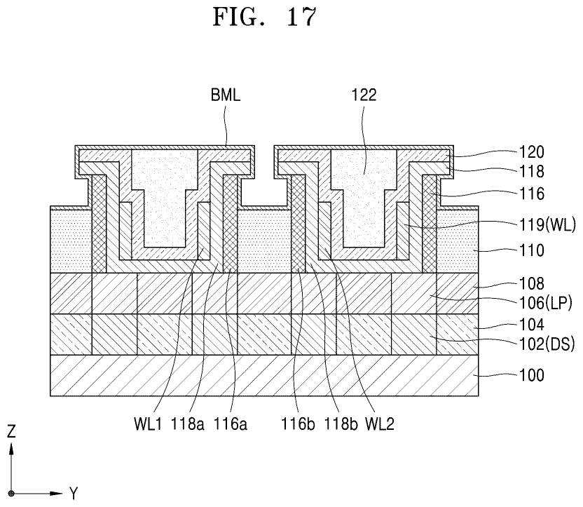

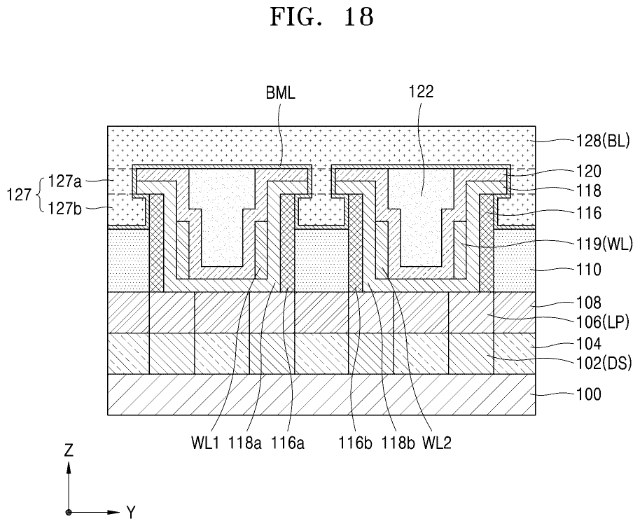

Referring to FIGS. 17 and 18, a barrier metal layer BML is formed on the inner walls of the first contact hole 124 (FIG. 16) and the second contact hole 126 (FIG. 16), on the inner walls of the first and second channel layers 116a and 116b, and on the capping insulating layer 120 and the third interlayer insulating layer 122 as illustrated in FIG. 17.

As shown in FIG. 18, the bit line contact plug 127 is formed on the barrier metal layer BML in the first contact hole 124 (FIG. 16) and the second contact hole 126 (FIG. 16). The bit line contact plug 127 includes the first bit line contact plug 127a and the second bit line contact plug 127b. The first bit line contact plug 127a may be formed inside the first contact hole 124 (FIG. 16). The second bit line contact plug 127b may be formed inside the second contact hole 126 (FIG. 16).

Then, the bit lines 128 are formed on the first bit line contact plug 127a and the barrier metal layer BML. The bit lines 128 may be formed as a conductive pattern. The bit lines 128 may include the same material as the bit line contact plug 127. The bit lines 128 may form a single body with the bit line contact plug 127.

The bit line contact plug 127 and the bit lines 128 may be formed by performing a metal deposition process once. The bit line contact plug 127 and the bit lines 128 may be formed by using the same material. Then, the resulting structure after removing the substrate 100 may be bonded to the peripheral circuit structure PS (FIG. 2) described above.

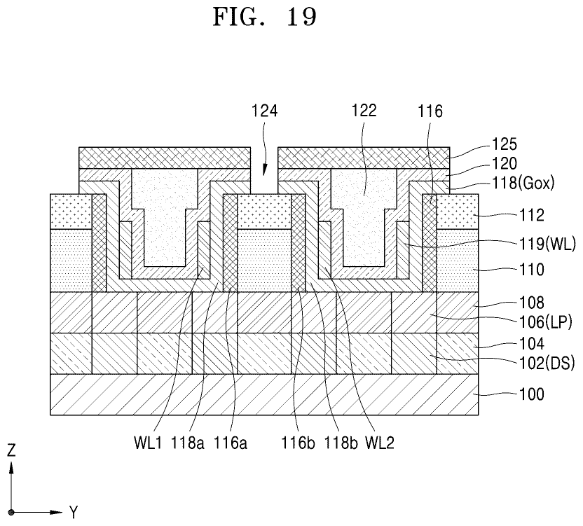

FIGS. 19 to 21 are cross-sectional views illustrating a method of manufacturing a semiconductor device, according to an embodiment.

Specifically, the manufacturing method in FIGS. 19 to 21 may be almost the same as that in FIGS. 10 to 18, except that in FIGS. 19 to 21, a mask layer 125 is formed on the capping insulating layer 120 and the third interlayer insulating layer 122, and an air gap AIG is formed inside the second bit line contact plug 127b.

In FIGS. 19 to 21, the same reference numerals as in FIGS. 4 to 9 indicate the same members. The descriptions given with reference to FIGS. 10 to 18 are briefly given or omitted when describing FIGS. 19 to 21.

The manufacturing processes in FIGS. 10 to 14 are performed. As a result, the capping insulating material layer 120r may be formed on the first and second channel layers 116a and 116b, and the third interlayer insulating layer 122 may be formed inside the mold trench 114 (FIG. 13).

Referring to FIG. 19, the capping insulating material layer 120r is formed on the first and second channel layers 116a and 116b, and the mask layer 125 is formed on the third interlayer insulating layer 122 inside the mold trench 114 (FIG. 13). In some embodiments, the mask layer 125 may include a hard mask layer. In some embodiments, the mask layer 125 may include a carbon-based material.

The mask layer 125 is used as an etching mask to etch the capping insulating material layer 120r and the gate insulating material layer 118r on the bit line sacrificial layer 112, thereby forming the first contact hole 124. The first contact hole 124 may expose the upper surface of the bit line sacrificial layer 112. The mask layer 125 may not be etched during the formation of the first contact hole 124. Since the mask layer 125 is not etched, the depth of the first contact hole 124 may be greater than that of the first contact hole 124 shown in FIG. 16.

As the capping insulating material layer 120r and the gate insulating material layer 118r are etched, the capping insulating material layer 120r and the gate insulating material layer 118r may become the capping insulating layer 120 and the gate insulating layers 118, respectively. The gate insulating layers 118 may correspond to the gate insulating layers Gox of FIG. 3. The gate insulating layers 118 may include the first and second gate insulating layers 118a and 118b, which are formed on sidewalls of the first and second word lines WL1 and WL2, respectively.

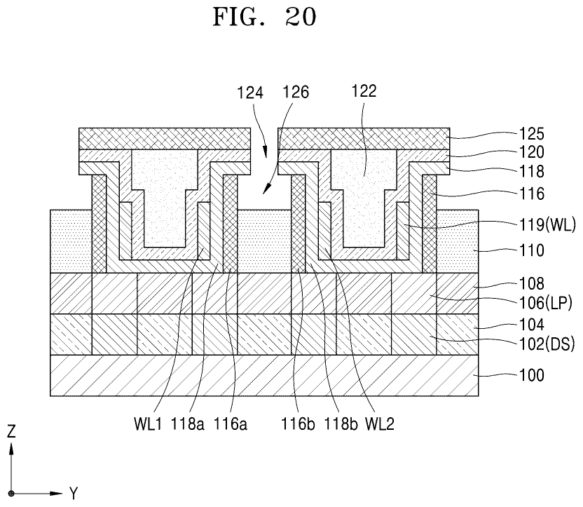

Referring to FIG. 20, the bit line sacrificial layer 112, exposed through the first contact hole 124, is etched to form the second contact hole 126. The first contact hole 124 and the second contact hole 126 may be connected to each other. The second contact hole 126 may have a greater width (or diameter) than the first contact hole 124. As the second contact hole 126 is formed, the upper surface of the channel isolation insulating layer 110 and the inner surfaces of the first and second channel layers 116a and 116b may be exposed. As described with reference to FIG. 9, in the region in which the bit line contact plug 127 is not formed, the bit line sacrificial layer 112 may not be etched during a subsequent process.

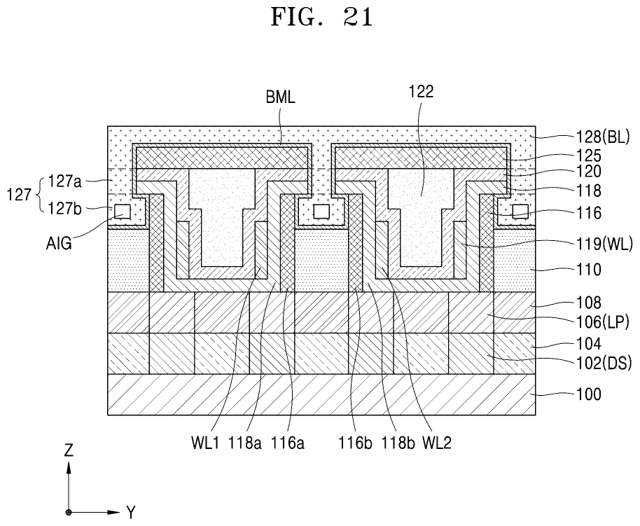

Referring to FIG. 21, the barrier metal layer BML is formed on the inner walls of the first contact hole 124 (FIG. 20) and the second contact hole 126 (FIG. 20), on the inner walls of the first and second channel layers 116a and 116b, and on the sidewalls and upper surface of the mask layer 125.

The bit line contact plug 127 is formed on the barrier metal layer BML in the first contact hole 124 (FIG. 20) and the second contact hole 126 (FIG. 20). The bit line contact plug 127 includes the first bit line contact plug 127a and the second bit line contact plug 127b.

The first bit line contact plug 127a may be formed inside the first contact hole 124 (FIG. 16). The second bit line contact plug 127b may be formed inside the second contact hole 126 (FIG. 16). Due to an increase in the depth of the first contact hole 124 (FIG. 20), a bit line contact material layer may not sufficiently fill the inside of the second bit line contact plug 127b, and the air gap AIG may be formed.

Subsequently, the bit lines 128 are formed on the first bit line contact plug 127a and the barrier metal layer BML. The bit lines 128 may be formed as a conductive pattern. The bit lines 128 may include the same material as the bit line contact plug 127. The bit lines 128 may form a single body with the bit line contact plug 127.

The bit line contact plug 127 and the bit lines 128 may be formed by performing a metal deposition process once. The bit line contact plug 127 and the bit lines 128 may be formed by using the same material.

In the semiconductor device described above, the air gap AIG is formed inside the second bit line contact plug 127b, thereby reducing the bit line capacitance between the bit lines 128 in the first horizontal direction (the X direction in FIG. 4). Accordingly, in the semiconductor device according to inventive concepts, the electrical characteristics thereof may be improved by reducing signal delay.

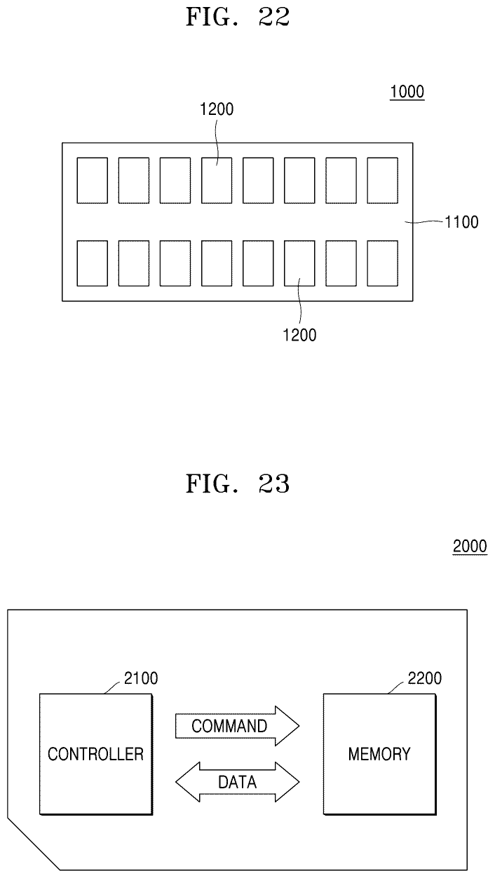

FIG. 22 is a plan view of a memory module including a semiconductor device according to inventive concepts.

Specifically, a memory module 1000 may include a printed circuit board 1100 and a plurality of semiconductor packages 1200. The plurality of semiconductor packages 1200 may include semiconductor devices according to embodiments of inventive concepts.

The memory module 1000 may include a single in-line memory module (SIMM), in which the plurality of semiconductor packages 1200 are mounted on only one surface of a printed circuit board, or a dual in-line memory module (DIMM), in which the plurality of semiconductor packages 1200 are arranged on both surfaces of a printed circuit board. Also, the memory module 1000 may include a fully buffered DIMM (FBDIMM) having an advanced memory buffer (AMB) that provides signals from the outside to each of the plurality of semiconductor packages 1200.

FIG. 23 is a schematic view of a memory card including a semiconductor device according to inventive concepts.

Specifically, in a memory card 2000, a controller 2100 and memory 2200 may exchange electrical signals. For example, when the controller 2100 provides a command, the memory 2200 may transmit data.

The controller 2100 may include a semiconductor device according to inventive concepts. The memory 2200 may include a semiconductor device according to inventive concepts. The memory card 2000 may include various types of memory cards, for example, memory stick cards, smart media cards (SM), secure digital cards (SD), mini-secure digital cards (mini-SD), and multimedia cards (MMC).

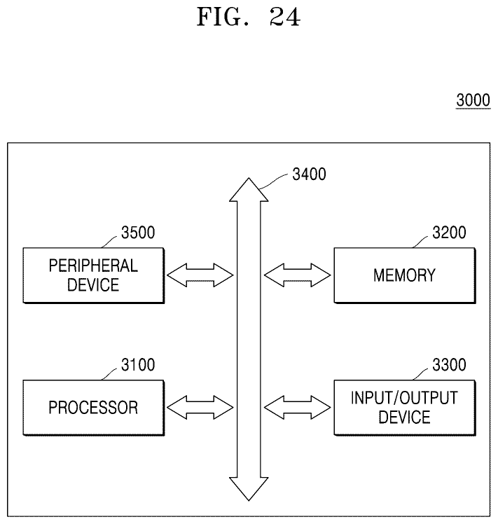

FIG. 24 is a schematic view of a system including a semiconductor device according to inventive concepts.

Specifically, in a system 3000, a processor 3100, memory 3200, and an input/output device 3300 may exchange data with each other by using a bus 3400. The memory 3200 in the system 3000 may include random-access memory (RAM) and read-only memory (ROM). Also, the system 3000 may include a peripheral device 3500, such as a floppy disk drive and a compact disk (CD) ROM drive.

The memory 3200 may include a semiconductor device according to the inventive concept. The memory 3200 may store code and data for operating the processor 3100. The system 3000 may be used in a mobile phone, an MPEG Audio Layer 3(MP3 ) player, a navigation unit, a portable multimedia player (PMP), a solid state disk (SSD), or household appliances.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A semiconductor device comprising:
a plurality of word lines extending in a first horizontal direction and spaced apart from each other in a second horizontal direction,
the second horizontal direction being perpendicular to the first horizontal direction,
the plurality of word lines including a conductive pattern,
the conductive pattern extending in a vertical direction,
the vertical direction being perpendicular to a plane in which the first horizontal direction extends and the second horizontal direction extends,
the plurality of word lines including a first word line and a second word line, and
the first word line and the second word line being adjacent to each other in the second horizontal direction;
a first gate insulating layer on an inner wall of the first word line and a second gate insulating layer on an inner wall of the second word line, the first gate insulating layer extending higher than the first word line in the vertical direction and the second gate insulating layer extending higher than the second word line in the vertical direction;
a first channel layer and a second channel layer extending in the vertical direction on an inner wall of the first gate insulating layer and an inner wall of the second gate insulating layer, respectively;
a channel isolation insulating layer between the first channel layer and the second channel layer;
a bit line contact plug below an upper surface of the first channel layer and an upper surface of the second channel layer, wherein the bit line contact plug is on the channel isolation insulating layer, and the bit line contact plug is in contact with both the first channel layer and the second channel layer; and
a bit line electrically connected to the bit line contact plug, the bit line extending in the second horizontal direction.

2. The semiconductor device of claim 1, wherein
the first gate insulating layer and the second gate insulating layer respectively extend from an outer wall of the first channel layer and an outer wall of the second channel layer onto the upper surface of the first channel layer and the upper surface of the second channel layer, and onto an upper surface of the bit line contact plug.

3. The semiconductor device of claim 2, further comprising:
a capping insulating layer on an upper surface of the first word line, an upper surface of the second word line, a side surface of the first word line, and a side surface of the second word line, wherein
the capping insulating layer is on an upper surface of the first gate insulating layer, an upper surface of the second gate insulating layer, a side surface of the first gate insulating layer, and a side surface of the second gate insulating layer on the bit line contact plug.

4. The semiconductor device of claim 3, wherein
the bit line contact plug comprises a first bit line contact plug and a second bit line contact plug, the first bit line contact plug passes through the capping insulating layer, the first gate insulating layer and the second gate insulating layer, and the second bit line contact plug is in contact with both the first channel layer and the second channel layer, and the second bit line contact plug is on the channel isolation insulating layer.

5. The semiconductor device of claim 4, wherein the second bit line contact plug defines an air gap inside the second bit line contact plug.

6. The semiconductor device of claim 1, wherein
a length of the first channel layer in the second horizontal direction and a length of the second channel layer in the second horizontal direction are each less than a length of the first channel layer in the vertical direction and a length of the second channel layer in the vertical direction.

7. The semiconductor device of claim 1, wherein the first channel layer and the second channel layer each comprise a first contact section in contact with the bit line contact plug and a second contact section in contact with the channel isolation insulating layer.

8. The semiconductor device of claim 1, wherein the upper surface of the first channel layer and the upper surface of the second channel layer are higher than upper surfaces of the plurality of word lines in the vertical direction.

9. The semiconductor device of claim 1, further comprising:
a first data storage element;
a second data storage element;
a first landing pad connected to the first data storage element; and
a second landing pad connected to the second data storage element, wherein
the first data storage element and the first landing pad are below the first channel layer, and
the second data storage element and the second landing pad are below the second channel layer.

10. The semiconductor device of claim 1, wherein the first channel layer and the second channel layer each comprise a semiconductor pattern including an oxide semiconductor.

11. A semiconductor device comprising:
a plurality of word lines extending in a first horizontal direction and spaced apart from each other in a second horizontal direction,
the second horizontal direction being perpendicular to the first horizontal direction,
the plurality of word lines including a conductive pattern,
the conductive pattern extending in a vertical direction,
the vertical direction being perpendicular to a plane in which the first horizontal direction extends and the second horizontal direction extends,
the plurality of word lines including a first word line and a second word line, and
the first word line and the second word line being adjacent to each other in the second horizontal direction;
a first gate insulating layer on an inner wall of the first word line and a second gate insulating layer on an inner wall of the second word line, the first gate insulating layer extending higher than the first word line in the vertical direction and the second gate insulating layer extending higher than the second word line in the vertical direction;
a first channel layer and a second channel layer extending higher in the vertical direction than the first word line and the second word line, the first channel layer being on an inner wall of the first gate insulating layer and the second channel layer being on an inner wall of the second gate insulating layer;
a channel isolation insulating layer between the first channel layer and the second channel layer, the channel isolation insulating layer being lower than the first channel layer and the second channel layer in the vertical direction;
a bit line contact plug on the channel isolation insulating layer and in contact with both the first channel layer and the second channel layer, wherein the bit line contact plug is in an opening recessed below an upper surface of the first channel layer and an upper surface of the second channel layer and the opening is defined by a space between the first channel layer and the second channel layer;
a plurality of bit lines electrically connected to the bit line contact plug and extending in the second horizontal direction, the plurality of bit lines including a first bit line and a second bit line adjacent to each other in the first horizontal direction; and
an interlayer insulating layer between the plurality of word lines, the interlayer insulating layer being outside of the first word line and the second word line, wherein the interlayer insulating layer is between the first bit line and the second bit line in the first horizontal direction.

12. The semiconductor device of claim 11, further comprising:
a capping insulating layer on an upper surface of the first word line, an upper surface of the second word line, a side surface of the first word line, and a side surface of the second word line, wherein the first gate insulating layer and the second gate insulating layer extend from an outer wall of the first channel layer and an outer wall of the second channel layer onto the upper surface of the first channel layer, the upper surface of the second channel layer, and onto an upper surface of the bit line contact plug, and
the capping insulating layer is on an upper surface of the first gate insulating layer, an upper surface of the second gate insulating layer, a side surface of the first gate insulating layer, and a side surface of the second gate insulating layer.

13. The semiconductor device of claim 12, wherein
the bit line contact plug comprises a first bit line contact plug and a second bit line contact plug,
the first bit line contact plug passes through the capping insulating layer, the first gate insulating layer, and the second gate insulating layer,
the first bit line contact plug is in a contact hole defined by the capping insulating layer, the first gate insulating layer, and the second gate insulating layer,
the second bit line contact plug is in the opening and in contact with both the first channel layer and the second channel layer.

14. The semiconductor device of claim 13, wherein the plurality of bit lines are electrically connected to each other via the first bit line contact plug.

15. The semiconductor device of claim 13, wherein the second bit line contact plug defines an air gap inside the second bit line contact plug.

16. The semiconductor device of claim 11, wherein
the first channel layer and the second channel layer each include a semiconductor pattern comprising an oxide semiconductor,
the first channel layer and the second channel layer each comprise a first contact section in contact with the bit line contact plug and a second contact section in contact with the channel isolation insulating layer.

17. A semiconductor device comprising:
a peripheral circuit structure; and
a cell array structure on the peripheral circuit structure, wherein the cell array structure comprises
a plurality of word lines extending in a first horizontal direction and spaced apart from each other in a second horizontal direction, the second horizontal direction being perpendicular to the first horizontal direction, the plurality of word lines including a conductive pattern, the conductive pattern extending in a vertical direction, the vertical direction being perpendicular to a plane in which the first horizontal direction extends and the second horizontal direction extends, the plurality of word lines including a first word line and a second word line, and the first word line and the second word line being adjacent to each other in the second horizontal direction,
a first gate insulating layer on an inner wall of the first word line and a second gate insulating layer on an inner wall of the second word line, the first gate insulating layer extending higher than the first word line in the vertical direction and the second gate insulating layer extending higher than the second word line in the vertical direction,
a first channel layer and a second channel layer extending in the vertical direction on an inner wall of the first gate insulating layer and an inner wall of the second gate insulating layer, respectively,
a channel isolation insulating layer between the first channel layer and the second channel layer,
a bit line contact plug below an upper surface of the first channel layer and an upper surface of the second channel layer, wherein the bit line contact plug is on the channel isolation insulating layer, and the bit line contact plug is in contact with both the first channel layer and the second channel layer,
a bit line electrically connected to the bit line contact plug, the bit line extending in the second horizontal direction, and
data storage elements electrically connected respectively to the first channel layer and the second channel layer via landing pads in contact with the first channel layer and the second channel layer.

18. The semiconductor device of claim 17, wherein
the cell array structure comprises memory cells,
the memory cells each comprise a vertical channel transistor,
the vertical channel transistor comprises the first channel layer, the second channel layer, the first gate insulating layer, the second gate insulating layer, the first word line, the second word line, and the data storage elements.

19. The semiconductor device of claim 17, further comprising:
a capping insulating layer on an upper surface of the first word line, an upper surface of the second word line, a side surface of the first word line, and a side surface of the second word line, wherein
the first gate insulating layer and the second gate insulating layer respectively extend from an outer wall of the first channel layer and an outer wall of the second channel layer onto the upper surface of the first channel layer and the upper surface of the second channel layer, and onto an upper surface of the bit line contact plug, and
the capping insulating layer is on an upper surface of the first gate insulating layer, an upper surface of the second gate insulating layer, a side surface of the first gate insulating layer, and a side surface of the second gate insulating layer on the bit line contact plug.

20. The semiconductor device of claim 19, wherein
the bit line contact plug comprises a first bit line contact plug and a second bit line contact plug,
the first bit line contact plug passes through the capping insulating layer, the first gate insulating layer, and the second gate insulating layer,
the first bit line contact plug is in a first contact hole defined by the capping insulating layer, the first gate insulating layer, and the second gate insulating layer,
the second bit line contact plug is in a second contact hole recessed from the upper surface of the first channel layer and the upper surface of the second channel layer,
the second contact hole is defined by a space between the first channel layer and the second channel layer,
the second bit line contact plug in contact with both the first channel layer and the second channel layer,
the bit line is among a plurality of bit lines in the cell array structure, and
the plurality of bit lines are electrically connected to each other via the first bit line contact plug.
